(19) United States
(12) Patent Application Publication
(10) Pub. No.: US 2023/0371265 A1
(43) Pub. Date: Nov. 16, 2023

(54) SEMICONDUCTOR MEMORY DEVICE

(71) Applicant: SAMSUNG ELECTRONICS CO., LTD., Suwon-si (KR)

(72) Inventors: Bongyong Lee, Suwon-si (KR); Myunghun Woo, Suwon-si (KR); Yongseok Kim, Suwon-si (KR)

(73) Assignee: SAMSUNG ELECTRONICS CO., LTD., Suwon-si (KR)

(21) Appl. No.: 18/136,993

(22) Filed: Apr. 20, 2023

(30) Foreign Application Priority Data
May 13, 2022 (KR) 10-2022-0058705

(51) Int. Cl. H10B 51/20; H10B 51/10; H01L 29/417; H01L 29/51

(52) U.S. Cl. CPC H10B 51/20; H10B 51/10; H01L 29/41725; H01L 29/516

(57) ABSTRACT

A semiconductor memory device is provided. The semiconductor memory device includes: a conductive layer on a substrate; an insulating isolation layer on the conductive layer; a stack structure on the insulating isolation layer, the stack structure including a plurality of source/drain contact layers and a plurality of gate electrode layers alternately provided along a first direction, perpendicular to an upper surface of the substrate; a vertical channel layer extending through the stack structure and the insulating isolation layer, wherein the vertical channel layer is in contact with each of the plurality of source/drain contact layers, and is connected to the conductive layer; and a gate insulating layer between each of the plurality of gate electrode layers and the vertical channel layer.

### CROSS-REFERENCE TO RELATED APPLICATION

This application claims priority to Korean Patent Application No. 10-2022-0058705, filed on May 13, 2022, in the Korean Intellectual Property Office, the disclosure of which is incorporated herein by reference in its entirety.

### BACKGROUND

### 1. Field

The present disclosure relates to a three-dimensional semiconductor memory device.

### 2. Description Of Related Art

There is an ongoing need to increase a degree of integration of semiconductor devices. In the case of a two-dimensional (2D) or planar semiconductor device, because the degree of integration is mainly determined by an area occupied by a unit memory cell, a level of a fine pattern forming technique affects the degree of integration.

Due to advance in manufacturing techniques, the degree of integration of the 2D semiconductor device is increasing, but is still limited. Accordingly, three-dimensional (3D) semiconductor memory devices including three-dimensionally arranged memory cells have been proposed.

### SUMMARY

One or more example embodiments provide a semiconductor memory device having improved read and/or erase characteristics.

According to an aspect of an example embodiment, a semiconductor memory device includes: a conductive layer on a substrate; an insulating isolation layer on the conductive layer; a stack structure on the insulating isolation layer, the stack structure including a plurality of source/drain contact layers and a plurality of gate electrode layers alternately provided along a first direction, perpendicular to an upper surface of the substrate; a vertical channel layer extending through the stack structure and the insulating isolation layer, wherein the vertical channel layer is in contact with each of the plurality of source/drain contact layers, and is connected to the conductive layer; and a gate insulating layer between each of the plurality of gate electrode layers and the vertical channel layer.

According to an aspect of an example embodiment, a semiconductor memory device, includes: a conductive layer on a substrate and doped with a first conductivity-type impurity; an insulating isolation layer on the conductive layer; a plurality of source/drain contact layers on the insulating isolation layer, and spaced apart from each other in a first direction, perpendicular to an upper surface of the substrate; a plurality of gate electrode layers respectively disposed between the plurality of source/drain contact layers; a vertical channel layer extending through the plurality of source/drain contact layers, the plurality of gate electrode layers, and the insulating isolation layer to be connected to the conductive layer, and doped with a first conductivity-type impurity in a first concentration; source/drain regions of the vertical channel layer that are doped with a second conductivity-type impurity and are in contact with the plurality of source/drain contact layers; and a plurality of gate insulating layers between side surfaces of the plurality of gate electrode layers and the vertical channel layer, and between the plurality of gate electrode layers and the plurality of source/drain contact layers.

According to an aspect of an example embodiment, a semiconductor memory device, including: a conductive layer on a substrate; an insulating isolation layer on the conductive layer; a first stack structure on the insulating isolation layer, the first stack structure including a plurality of first source/drain contact layers arranged to be spaced apart from each other in a first direction, perpendicular to an upper surface of the substrate, and at least one first gate electrode layer respectively between the plurality of first source/drain contact layers; a second stack structure on the first stack structure, the second stack structure including a plurality of second source/drain contact layers arranged to be spaced apart from each other in the first direction, and at least one second gate electrode layer respectively between the plurality of second source/drain contact layers; a device isolation film between the first stack structure and the second stack structure; a vertical channel layer extending through the first stack structure, the second stack structure, the device isolation film, and the insulating isolation layer, in contact with each of the plurality of first and second source/drain contact layers, and connected to the conductive layer; and a gate insulating layer between each of the at least one first gate electrode layer and the vertical channel layer, and between each of the at least one second gate electrode layer and the vertical channel layer.

### BRIEF DESCRIPTION OF DRAWINGS

The above and other aspects and features will be more apparent from the following description of example embodiments, taken in conjunction with the accompanying drawings, in which:

FIG. 1 is a cross-sectional view illustrating a semiconductor memory device according to an example embodiment.

FIGS. 2A and 2B are plan cross-sectional views of the semiconductor memory device illustrated in FIG. 1, respectively, taken along lines IT and II-IF according to an example embodiment.

FIG. 3 is a circuit diagram of a unit cell of the semiconductor memory device illustrated in FIG. 1 according to an example embodiment.

FIGS. 4 to 6 are schematic diagrams illustrating an operation of a unit cell of a semiconductor memory device, respectively.

FIG. 7 is an overall circuit diagram of the semiconductor memory device illustrated in FIG. 1 according to an example embodiment.

FIG. 8 is a cross-sectional view illustrating a semiconductor memory device according to an example embodiment.

FIGS. 9 and 10 are a plan view and a cross-sectional view illustrating a semiconductor memory device according to an example embodiment, respectively.

FIGS. 11A, 11B, 11C, 11D, 11E, 11F and 11G are cross-sectional views illustrating a method of manufacturing a semiconductor memory device according to an example embodiment.

### DETAILED DESCRIPTION

Hereinafter, example embodiments will now be described more fully with reference to the accompanying drawings. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

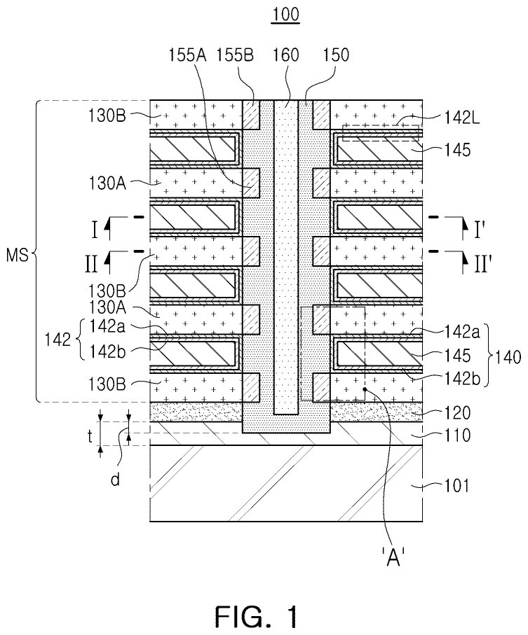

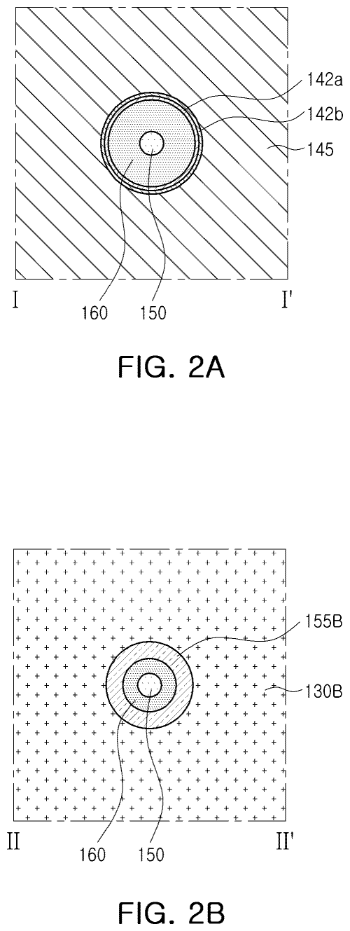

FIG. 1 is a cross-sectional view illustrating a semiconductor memory device according to an example embodiment, and FIGS. 2A and 2B are planar cross-sectional views of the semiconductor memory device illustrated in FIG. 1, respectively, taken along lines I-I′ and II-II′.

Referring to FIGS. 1, 2A, and 2B, a semiconductor memory device 100 includes a conductive layer 110 disposed on a substrate 101, an insulating isolation layer 120 disposed on the conductive layer 110, a memory cell stack structure MS disposed on the insulating isolation layer 120, and a vertical channel layer 150 penetrating through the memory cell stack structure MS and the insulating isolation layer 120.

The substrate 101 may be a semiconductor substrate. For example, the semiconductor substrate may be a silicon (Si) substrate, a germanium (Ge) substrate, a silicon germanium (SiGe), a gallium arsenide (GaAs), or an indium phosphorus (InP) substrate. In some example embodiments, the semiconductor substrate may be a substrate doped with N-type or P-type impurities. In other example embodiments, the substrate 101 may be a silicon-on-insulator substrate.

The memory cell stack structure MS includes a plurality of source/drain contact layers 130A and 130B arranged to be spaced apart from each other in a direction, perpendicular to an upper surface of the substrate 101, and a plurality of gate structures 140 respectively disposed between the plurality of source/drain contact layers 130A and 130B.

Each of the plurality of gate structures 140 is disposed between two adjacent source/drain contact layers 130A and 130B and constitutes a unit memory cell. In addition, each of the source/drain contact layers 130A and 130B positioned between two adjacent gate structures 140 may be used as a source contact or a drain contact shared with two adjacent unit memory cells. The configuration of such a memory cell will be described in detail with reference to FIG. 4.

Each of the plurality of gate structures 140 includes a gate electrode layer 145 and a gate insulating layer 142. The gate insulating layers 142 may be disposed between side surfaces of the plurality of gate electrode layers 145 and the vertical channel layer 150, respectively.

The plurality of source/drain contact layers 130A and 130B and the plurality of gate electrode layers 145 may include a conductive material, respectively. For example, the conductive material may include a metal such as doped poly-Si (Poly-Si) or tungsten (W) and/or a conductive metal nitride.

The gate insulating layer 142 may include a ferroelectric film 142b and an interface insulating film 142a disposed between the ferroelectric film 142b and the vertical channel layer 150.

The ferroelectric film 142b may store information using a polarization phenomenon of the ferroelectric film 142b that is inverted according to an applied voltage. The semiconductor memory device 100 may be used as a non-volatile memory. The ferroelectric film 142b may include a material capable of having remnant polarization. For example, the ferroelectric film 142b may include aluminum oxide (Al2O3), tantalum oxide (Ta2O3), titanium oxide (TiO2), yttrium oxide (Y2O3), zirconium oxide (ZrO2), zirconium silicon oxide (ZrSixOy), hafnium oxide (HfO2), hafnium silicon oxide. (HfSixOy), lanthanum oxide (La2O3), lanthanum aluminum oxide (LaAlxOy), lanthanum hafnium oxide (LaHfxOy), hafnium aluminum oxide (HfAlxOy), and praseodymium oxide (Pr2O3).

The interface insulating film 142a may be disposed between the vertical channel layer 150 and the ferroelectric film 142b. The interface insulating film 142 serves to reduce a concentration of defect sites generated at an interface when the ferroelectric layer 142b is in direct contact with (e.g., grown on) surfaces of the plurality of source/drain contact layers 130A and 130B and the vertical channel layer 150. For example, the interfacial insulating film 142a may include silicon oxide, silicon nitride, silicon carbide, silicon oxynitride, silicon oxycarbide, or silicon carbonitride.

In addition, each of the gate insulating layers 142 includes a horizontal insulating portion 142L extending between the source/drain contact layers 130A and 130B and the gate electrode layers 145. The horizontal insulating portion 142L serves to electrically separate the source/drain contact layers 130A and 130B and the gate electrode layers 145.

Referring to FIG. 1, the vertical channel layer 150 may be configured to penetrate through the memory cell stack structure MS in a direction, perpendicular to an upper surface of the substrate 101 to be in contact with a plurality of source/drain contact layers 130A and 130B and gate insulating layers of the plurality of gate structures 140.

The vertical channel layer 150 may have a cylindrical structure, and may have a core insulating portion 150 filled in the vertical channel layer 150. As illustrated in FIGS. 2A and 2B, an outer side surface of the vertical channel layer 150 surrounding the core insulating portion 160 may be surrounded by a memory cell stack structure MS so as to be in contact with the source/drain contact layers 130A and 130B and the gate insulating layers 142 of the gate structure 140 as described above.

The vertical channel layer 150 may include a doped semiconductor material. For example, the vertical channel layer 150 may include polysilicon doped with a first conductivity-type impurity (e.g., a P-type impurity). In addition, the vertical channel layer 150 may have source/drain regions 155A and 155B doped with a conductivity-type impurity (e.g., a N-type impurity) opposite to the impurity (e.g., a P-type impurity) of the vertical channel layer 150 in regions in contact with the source/drain contact layers 130A and 130B. A region between adjacent source/drain regions 135A and 135B may serve as a channel region.

In example embodiments, the vertical channel layer 150 extending toward the substrate 101 may also penetrate through an insulating isolation layer 120 to be connected to the conductive layer 110. The insulating isolation layer 120 may electrically isolate the memory cell stack structure MS, in particular, a lowest source/drain contact layer 130B, from the conductive layer 110. For example, the conductive layer 110 may include a metal such as doped polysilicon or tungsten (W) and/or a conductive metal nitride.

In some example embodiments, the conductive layer 110 may include the same material as the vertical channel layer 150. For example, the conductive layer 110 may include polysilicon doped with a first conductivity-type impurity (e.g., a P-type impurity).

In addition, the insulating isolation layer 120 may be used as an etch stop layer for adjusting a formation depth of a hole (or a channel hole) for the vertical channel layer 150. The insulating isolation layer 120 may include a compound containing aluminum (Al). For example, the insulating isolation layer 120 may include aluminum oxide (Al2O3).

Referring to FIG. 1, a portion of the vertical channel layer 150 extending in the conductive layer 110 may be smaller than a thickness of the conductive layer 110. Thus, side and bottom surfaces of the vertical channel layer 150 may contact the conductive layer 110. As described above, because the extended portion of the vertical channel layer 150 is located in the conductive layer 110, it may have a relatively large contact area with the conductive layer 110.

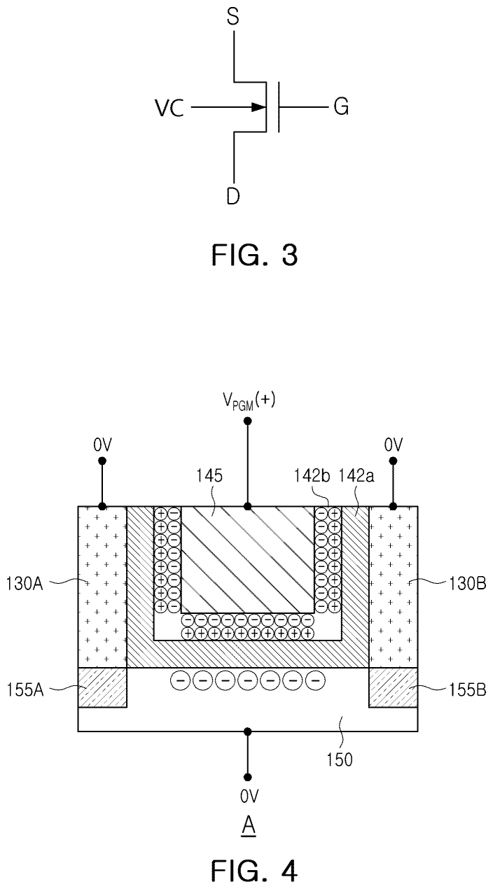

As described above, the semiconductor memory device 100 includes a conductive layer 110 connected to the vertical channel layer 150. Additionally, a voltage VC applied to the vertical channel layer 130 through the conductive layer 110 may be controlled to improve the characteristics of read and erase operations. These improvements will be described in detail with reference to FIGS. 3 and 4.

FIG. 3 is a circuit diagram of a unit memory cell indicated by “A” of the semiconductor memory device 100 illustrated in FIG. 1, and FIGS. 4 to 6 are schematic diagrams illustrating operations of the memory cell, respectively.

FIGS. 4 to 6 are schematic diagrams illustrating a Program or Write, erase, and read process, respectively, and operate by applying a source/drain voltage and a gate voltage as illustrated in Table 1 below.

TABLE 1

| Classification | Program (write) | Erase | Read |
|---|---|---|---|
| Drain (D) | 0 V | 0 V | BL |
| Gate (G) | V_{pgm} (+) | Vₑᵣₛ (−) | V_{read} |
| Source (S) | 0 V | 0 V | Vₛₛ |
| Channel (VC) | 0 V | >0 V | >0 V |

Referring to FIG. 4, when a positive voltage (+) is applied to the gate electrodes 145 (G) during writing, electrons are concentrated in a channel region, adjacent to the gate electrode 145 by polarization as illustrated in FIG. 4 in the ferroelectric film 142b, to form a channel.

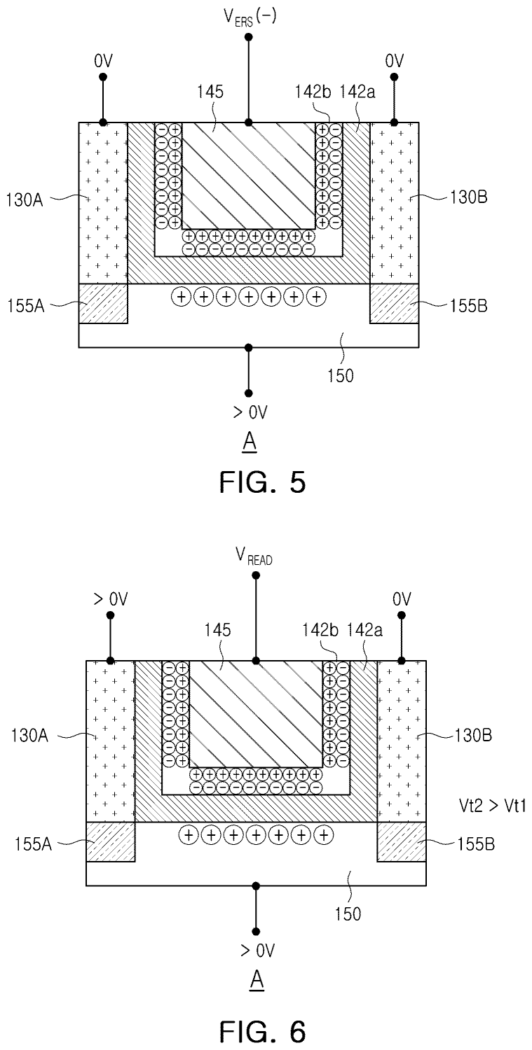

Referring to FIG. 5, during erasing, a negative voltage (−) is applied to a gate electrode 145 (G), to reverse polarization during writing in a ferroelectric film 142b to concentrate holes in a channel region, adjacent to the gate electrode 145. In this case, when there is no supply source of separate holes, because movement of holes depends only on the reversed polarization, it is difficult to expect a fast erase speed, but in example embodiments, a fast erase speed may be expected due to holes supplied by applying a voltage to the vertical channel layer 150 through the conductive layer 110.

In addition, referring to FIG. 6, in a process of reading through a drain electrode by applying a voltage (Vss) to a source electrode S, there is a problem in that a channel length may be shortened due to a decrease in a length (or a thickness) of the gate electrode and the read characteristic is deteriorated due to an undesired leakage current, but deterioration of read characteristics due to an increase in leakage current may be prevented by applying a constant voltage (>0V) to the vertical channel layer 130 through the conductive layer 110 to have a higher threshold voltage (Vt2) than the existing threshold voltage (Vt1).

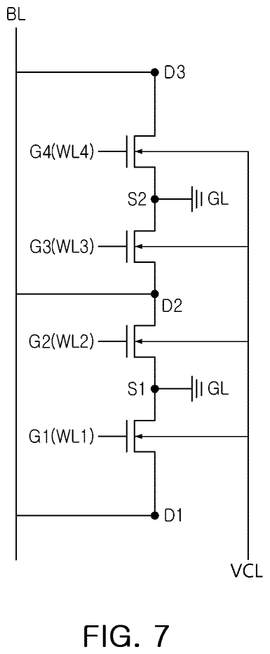

Referring to FIG. 7 together with FIG. 1, the semiconductor memory device 100 may consist of first to fourth memory cells MC1, MC2, MC3, and MC4. As described above, in each of the memory cells MC1, MC2, MC3, and MC4, four gate structures 140, in particular, each of four gate electrode layers 145 act as gate electrodes G1, G2, G3, and G4, and each of source/drain contact layers 130A and 130B positioned above and below each of the gate structures 140 act as source electrodes S1 and S2, and drain electrodes D1, D2 and D3.

The source/drain contact layers 130A and 130B positioned between two adjacent gate structures 140 may be used as source or drain electrodes shared by adjacent memory cells. Specifically, each of the first and second memory cells MC1 and MC2 and third and fourth memory cells shares first and second source electrodes S1 and S2, and the second third memory cells MC2 and MC3 share a second source electrode S2. In addition, the source electrodes S1 and S2 may be commonly connected to ground lines GL, and the drain electrodes D1, D2, and D3 may be configured to be commonly connected to a bit line BL, as described with reference to FIG. 3, to perform write, read, and erase operations, as memory cells, respectively.

Each of the gate electrodes G1, G2, G3, and G4 may be connected, respectively, to first to fourth word lines WL1, WL2, WL3, and WL4, to apply a gate voltage independently to each of the four memory cells MC1, MC2, MC3, and MC4. As a result, the first to fourth memory cells MC1, MC2, MC3, and MC4 include source electrodes S1 and S2 and drain electrodes D1, D2, and D3, respectively, and independently control a gate voltage applied to the gate electrode G1, G2, G3, and G4, so that information stored in the ferroelectric film 142b may be individually connected. As described above, the semiconductor memory device 100 may implement an independent random access operation for each of the memory cells MC1, MC2, MC3, and MC4.

In addition, in an example embodiment, a channel voltage line VCL may be connected to the conductive layer 110 to control a channel voltage. As described above, by applying a voltage during the reading and erasing processes, the influence of the leakage current during reading can be reduced and an erase speed can be improved.

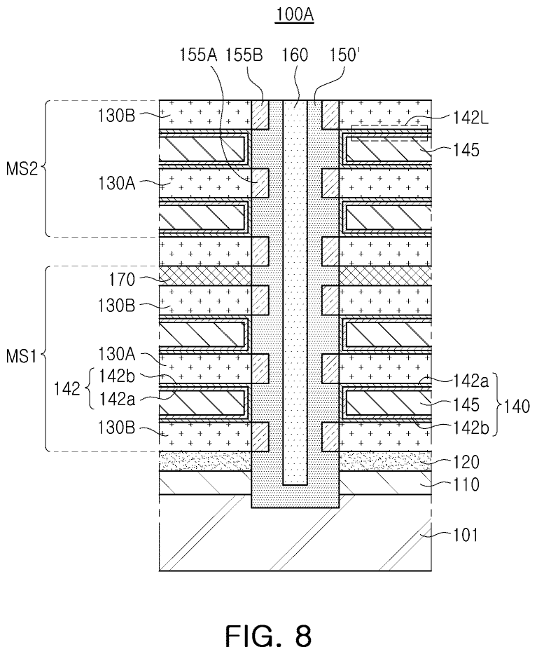

FIG. 8 is a cross-sectional view illustrating a semiconductor memory device according to an example embodiment.

Referring to FIG. 8, the semiconductor memory device 100A may be understood as similar to example embodiments discussed above with respect to FIGS. 1 to 6, except that that a memory cell stack structure is separated into two pieces MS1 and MS2 by a device isolation film 170 and a vertical channel layer 150′ is formed through the conductive layer 110. In addition, the components be understood with reference to the descriptions of the same or similar components of example embodiments discussed above with respect to FIGS. 1 to 6, unless otherwise specified.

The semiconductor memory device 100A may include a first memory cell stack structure MS1 and a second memory cell stack structure MS2 separated by a device isolation film 170. The second memory cell stack structure MS2 may be disposed on the first memory cell stack structure MS1 with the device isolation film 170 interposed therebetween.

Each of the first and second memory cell stack structures MS1 and MS2 may include a plurality of source/drain contact layers 130A and 130B arranged to be spaced apart from each other in a direction, perpendicular to an upper surface of the substrate 101 and a plurality of gate structures 140 respectively disposed between the plurality of source/drain contacts 130A and 130B.

In example embodiments, each of the first and second memory cell stack structures MS1 and MS2 constitutes two memory cells, and the device isolation film 170 may be disposed between an uppermost source/drain contact layer 130A of the first memory cell stack structure MS1 and a lowermost source/drain contact layer 130B of the second memory cell stack structure MS2.

A vertical channel layer 150′ may be formed to penetrate through the first and second memory cell stack structures MS1 and MS2, the insulating isolation layer 120, and the conductive layer 110. As described above, the vertical channel layer 150′ may be shared by the first and second memory cell stack structures MS1 and MS2. In addition, similarly to example embodiments discussed above, the vertical channel layer 150′ may be connected to the conductive layer 110, and an erase speed and read characteristics may be improved by controlling a voltage in a channel region of each memory cell through the conductive layer.

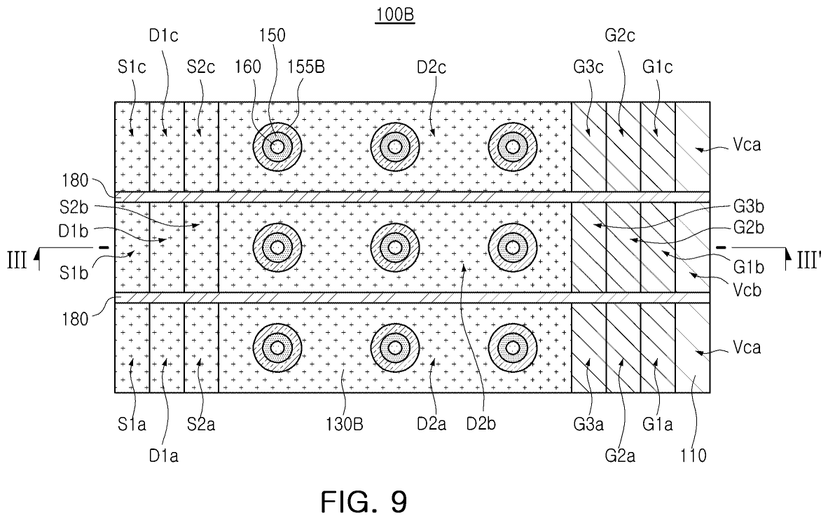

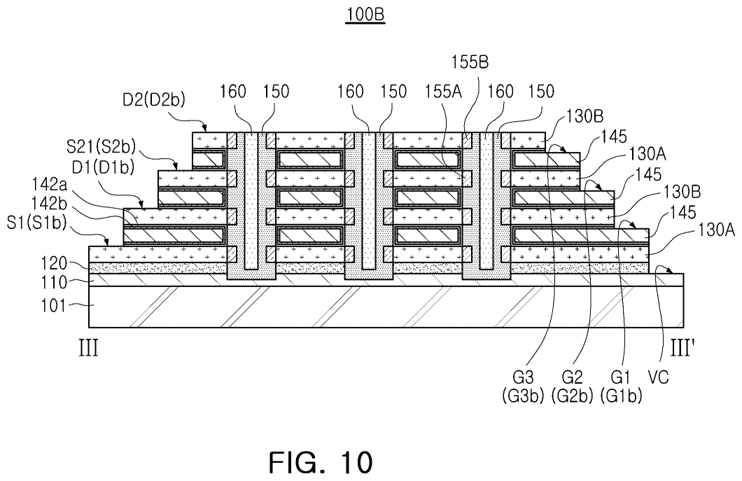

FIGS. 9 and 10 are a plan view and a cross-sectional view illustrating a semiconductor memory device according to an example embodiment, respectively.

Referring to FIGS. 9 and 10, a semiconductor memory device 100B according to example embodiments includes a conductive layer 110 disposed on a substrate 101, an insulating isolation layer 120 disposed on the conductive layer 110, and a memory cell stack structure disposed on the insulating isolation layer 120.

The memory cell stack structure may include a plurality of vertical channel layers 150 arranged at regular intervals in a planar view (refer to FIG. 9). In addition, the memory cell stack structure includes two isolation structures 180 formed in a row direction to be separated into three regions. Each separated stack structure may include three vertical channel layers 150 arranged in a row direction. The two isolation structures 180 may be formed to a depth capable of being separated up to a conductive layer 110. In some example embodiments, the two isolation structures 180 may separate only the memory cell stack structure so that the conductive layer 110 is shared to memory cells in three regions.

Similarly to example embodiments discussed above, the memory cell stack structure includes a plurality of source/drain contact layers 130A and 130B arranged to be spaced apart from each other in a direction, perpendicular to an upper surface of the substrate 101, and a plurality of gate structures 140 respectively disposed between the plurality of source/drain contact layers 130A and 130B.

Referring to FIGS. 9 and 10, in both end portions of the memory cell stack structure, the source/drain contact layers 130A and 130B and the gate electrode layer 140 may be partially exposed to provide a contact region, to be connected to a via to be formed in a vertical direction.

Specifically, in one end portion of the memory cell stack structure, each of the source/drain contact layers 130A and 130B may provide four contact regions S1, D1, S2, and D2, and may be separated into three stacked structure regions divided by an isolation structure 180 again, to provide 12 contact regions S1a, S1b, S1c, D1a, D1b, D1c, S2a, S2b, S2c, D2a, D2b, and D2c. These contact regions may be connected in common or independently as needed.

Similarly, in the other end portion of the memory cell stack structure, each of the gate electrode layers 145 may provide three contact regions G1, G2, and G3, and separated into three stack structure regions divided by an isolation structure 180 again, to provide all nine contact regions G1a, G1b, G1c, G2a, G2b, G2c, G3a, G3b, and G3c. These contact regions may be connected in common or independently as needed.

Additionally, a contact region capable of exposing a portion of the conductive layer 110 at a lowermost step in the other end portion of the memory cell stack structure to control a voltage in a channel region may be provided. In example embodiments, the memory cell stack structure may be separated into three stack structure regions divided by the isolation structure 180 again, to provide three contact regions Vca, Vcb, and Vcc. In each of the three stack structure regions, a channel voltage of memory cells may be independently controlled. In another example embodiment, as described above, the conductive layer 110 is not separated by adjusting the formation depth of the isolation structure 180 or, as illustrated in FIG. 10, even though the conductive layer 110 is separated into each region and commonly connected thereto, an entire channel voltage may be commonly controlled.

Other components of may be understood with reference to descriptions of the same or similar components of example embodiments discussed above with respect to FIGS. 1 to 6, unless otherwise specified.

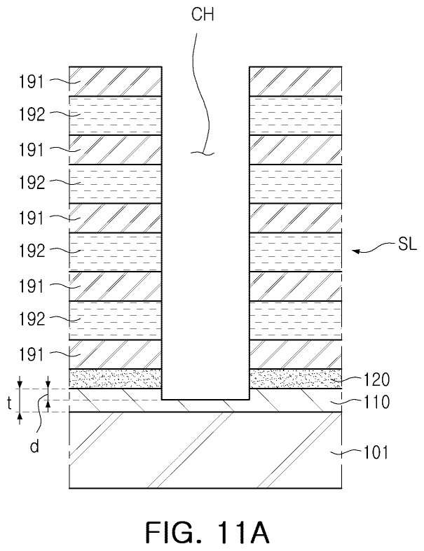

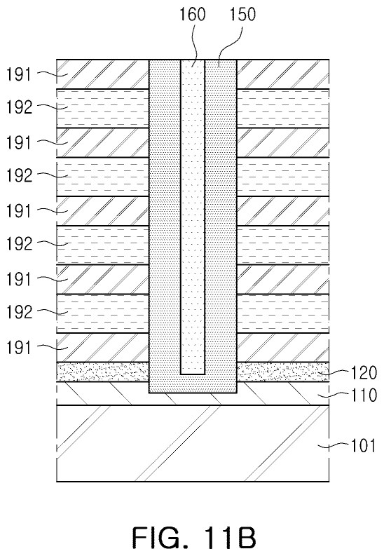

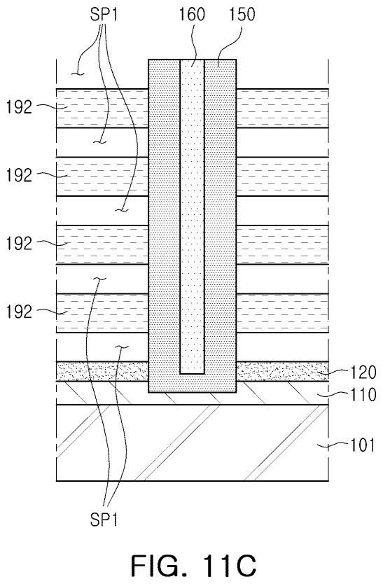

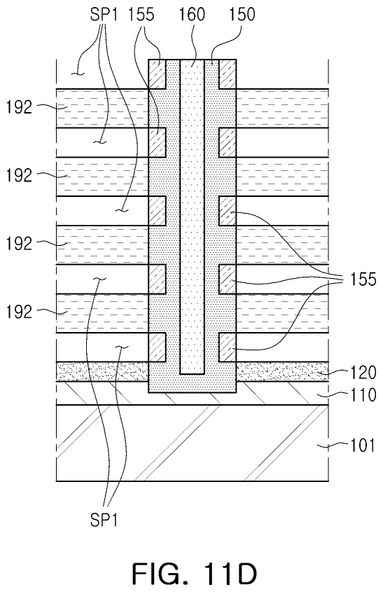

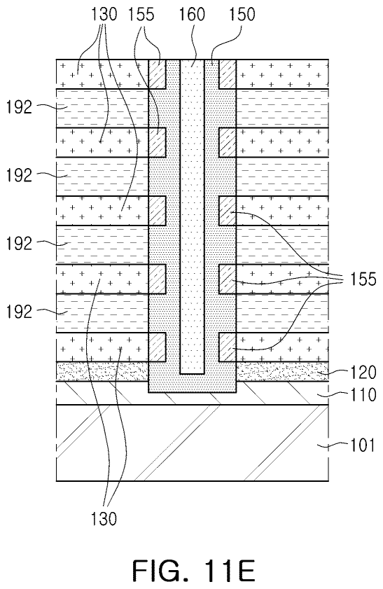

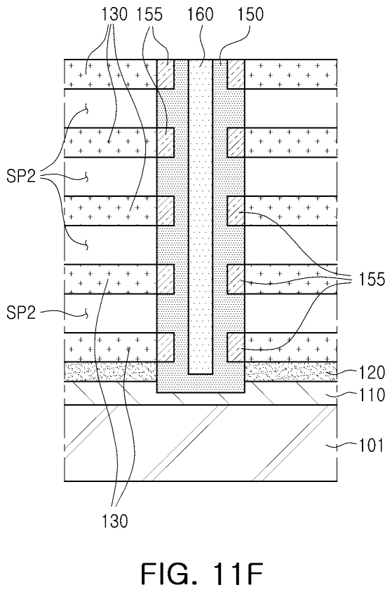

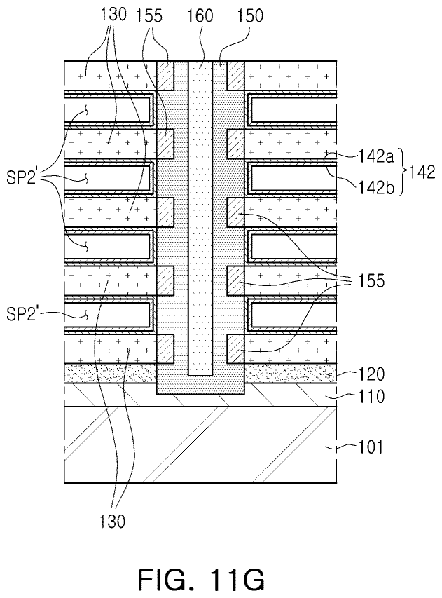

FIGS. 11A to 11G are cross-sectional views illustrating a method of manufacturing a semiconductor memory device according to an example embodiment.

Referring to FIG. 11A, a stack structure SL is formed on a substrate 101, and a channel hole CH penetrating through the stack structure SL is formed.

In example embodiments, the stack structure SL includes a conductive layer 110 and an insulating isolation layer 120, sequentially stacked on the substrate 101, and first and second sacrificial layers 191 and 192, alternately stacked on the insulating isolation layer 120. Here, each of the first sacrificial layers 191 defines a region for the source/drain contact layers, and each of the second sacrificial layers 192 defines a region for the gate structures.

The insulating isolation layer 120 may be formed of a material having etch selectivity with respect to the first and second sacrificial layers 191 and 192. In addition, the second sacrificial layers 192 may be formed of a material having etch selectivity with respect to the first sacrificial layers 191. For example, the first sacrificial layers 191 may include silicon oxide, and the second sacrificial layers 192 may include silicon nitride. In addition, the insulating isolation layer 120 may include an aluminum compound such as aluminum oxide.

A channel hole CH connected to the conductive layer 110 is formed in the stack structure SL. After performing a primary etching process on the first and second sacrificial layers 191 and 192 using the insulating isolation layer 120 as an etch stop layer, a secondary etching process may be performed on the insulating isolation layer 120. The first and second sacrificial layers 191 and 192 and the insulating isolation layer 120 may be exposed on a sidewall of the channel hole CH, and the conductive layer 110 may be exposed on a bottom region of the channel hole CH. The exposed region of the conductive layer 110 may serve as a contact region with a vertical channel layer (150 in FIG. 11B) to be formed in a subsequent process. In some example embodiments, the channel hole CH may have a cylindrical shape, and may have a circular or elliptical planar shape in a planar view, but example embodiments are not limited thereto.

Referring to FIG. 11B, a vertical channel layer 150 is formed in the channel hole CH, and an insulating core portion 160 may be formed by filling the vertical channel layer 150 with an insulating material.

The vertical channel layer 150 is formed to cover a sidewall and a bottom surface of the channel hole CH. The vertical channel layer 150 may include a doped semiconductor material, for example, polysilicon doped with a first conductivity-type impurity (e.g., a P-type impurity). The vertical channel layer 150 may be formed by a deposition process such as chemical vapor deposition or atomic deposition. The vertical channel layer 150 may be formed along the first and second sacrificial layers 191 and 192 positioned on the sidewall of the channel hole CH, and may be in contact with the conductive layer 110 on the bottom surface thereof Also, the vertical channel layer 150 may be formed on an upper surface of the stack structure SL, that is, an upper surface of the uppermost first sacrificial layer 191. The vertical channel layer 150 may be formed relatively conformally, and in the channel hole CH, the vertical channel layer 150 may have a hollow cylinder structure in an internal space.

An insulating core portion 160 may be formed by forming an insulating material to be filled in the internal space of the vertical channel layer 150. A portion of the insulating material may also be formed on the upper surface of the channel layer portion located on the upper surface of the stack structure SL. Next, the vertical channel layer 150 of the cylindrical structure and the insulating core portion 160 filled therein, illustrated in FIG. 11B may be formed by selectively removing the channel layer portion and the insulating material portion located on the upper surface of the stack structure SL. This selective removing process may be performed using a planarization process such as etching back or chemical mechanical polishing.

Referring to FIG. 11C, first interlayer spaces SP1 may be formed by removing the first sacrificial layers 191.

As described above, because the first sacrificial layers 191 are formed of materials having etch selectivity to that of the vertical channel layer 150 as well as materials of the second sacrificial layers 192 and the insulating isolation layer 120, the first sacrificial layers 191 can be selectively removed using an appropriate wet etching process. First interlayer spaces SP1 may be formed between the insulating isolation film and the second sacrificial layers, and a partial side region of the vertical channel layer 150 may be exposed through the first interlayer spaces SP1.

Referring to FIG. 11D, source/drain regions 155 are formed by implanting impurities into a region of a side surface of the vertical channel layer 150 selectively exposed through the first interlayer spaces SP1.

A specific conductivity-type impurity is implanted through the first interlayer spaces SP1 to form a high-concentration impurity region for the source/drain regions 155. When the vertical channel layer is a channel layer doped with a first conductivity-type impurity (e.g., P-type), the impurities for the source/drain regions 155 may be a second conductivity-type (e.g., N-type) impurity. For example, this process may be implemented by injecting a source gas containing a second conductivity-type impurity into a side region of the vertical channel layer 150 through the first interlayer spaces SP1 and then diffusing the same through a heat treatment process.

Referring to FIG. 11E, source/drain contact layers 130 may be formed in each of the first interlayer spaces SP1.

A conductive material may be filled in each of the first interlayer spaces SP1 to form a source/drain contact layer 130 in contact with the source/drain region 155. For example, the conductive material may include doped polysilicon or a metal such as tungsten and/or a conductive metal nitride. The conductive material filled in the source/drain contact layer 130 may have an etch selectivity with the second sacrificial layers 192.

The source/drain contact layer 130 positioned on the uppermost second sacrificial layer 192 may be deposited together in a process of depositing a conductive material in the other first interlayer spaces SP1, and in this process, by removing a portion located on the vertical channel layer 150 and the insulating core portion 160 using a planarization process such as CMP, as illustrated in FIG. 11E, an uppermost source/drain contact layer 130 having a flat upper surface with the vertical channel layer 150 and the insulating core portion 160 may be formed.

Referring to FIG. 11F, by removing second sacrificial layers 192, second interlayer spaces SP2 in which the other partial side regions of the vertical channel layer 150 are exposed may be formed.

As described above, because the second sacrificial layers 192 are made of a material having etch selectivity to a material of the source/drain contact layers 130 and a material of the vertical channel layer 150, they may be selectively removed by using an appropriate wet etching process. Second interlayer spaces SP2 may be formed between the source/drain contact layers 130, and the other partial side regions of the vertical channel layer 150 may be exposed through the second interlayer spaces SP2.

Referring to FIG. 11G, a gate insulating layer 142 is formed on the other partial side regions of the vertical channel layer 150 selectively exposed through the second interlayer spaces SP2.

An interface insulating layer 142a and a ferroelectric film 142b are sequentially formed on surfaces of the source/drain contact layer 130 and the vertical channel layer 150 located in the second interlayer spaces SP2. These deposition processes may use an atomic layer deposition method to form a conformal film.

For example, the interface insulating layer 142a may include silicon oxide, silicon nitride, silicon carbide, silicon oxynitride, silicon oxycarbide, or silicon carbonitride. For example, the ferroelectric film 142b may include aluminum oxide (Al2O3), tantalum oxide (Ta2O3), titanium oxide (TiO2), yttrium oxide (Y2O3), zirconium oxide (ZrO2), zirconium silicon oxide (ZrSixOy), and hafnium oxide (HfO2), hafnium silicon oxide (HfSixOy), lanthanum oxide (La2O3), lanthanum aluminum oxide (LaAlxOy), lanthanum hafnium oxide (LaHfxOy), hafnium aluminum oxide (HfAlxOy), or praseodymium oxide (Pr2O3). Because the ferroelectric film 142b must be crystallized for a desired polarization characteristic, when the deposited ferroelectric film 142b is in an amorphous state, a crystallization heat treatment may be applied.

The semiconductor memory device illustrated in FIG. 1 may be manufactured by forming a gate electrode layer 145 in the remaining second interlayer spaces SP2′.

As set forth above, according to an example embodiment, a semiconductor memory device includes a conductive layer connected to a vertical channel layer between a substrate and an insulating isolation layer. During an erase operation, an erase speed may be increased by supplying a carrier (e.g., a hole) to the vertical channel layer through the conductive layer. In addition, during a read operation, by applying a channel control voltage, it is possible to prevent deterioration of read characteristics due to cell leakage current.

While aspects of example embodiments have been particularly shown and described, it will be understood that various changes in form and details may be made therein without departing from the spirit and scope of the following claims.

What is claimed is:

1. A semiconductor memory device, comprising:
a conductive layer on a substrate;
an insulating isolation layer on the conductive layer;
a stack structure on the insulating isolation layer, the stack structure comprising a plurality of source/drain contact layers and a plurality of gate electrode layers alternately provided along a first direction, perpendicular to an upper surface of the substrate;
a vertical channel layer extending through the stack structure and the insulating isolation layer, wherein the vertical channel layer is in contact with each of the plurality of source/drain contact layers, and is connected to the conductive layer; and
a gate insulating layer between each of the plurality of gate electrode layers and the vertical channel layer.

2. The semiconductor memory device of claim 1, wherein the gate insulating layer comprises a ferroelectric film and an interface insulating film between the ferroelectric film and the vertical channel layer.

3. The semiconductor memory device of claim 2, wherein the ferroelectric film comprises any one or any combination of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide. (HfSiₓO_{y}),), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and. praseodymium oxide (Pr₂O₃).

4. The semiconductor memory device of claim 2, wherein the interface insulating film comprises silicon oxide, silicon nitride, silicon carbide, silicon oxynitride, silicon oxycarbide, or silicon carbonitride.

5. The semiconductor memory device of claim 1, wherein the gate insulating layer comprises a horizontal insulating portion between the plurality of source/drain contact layers and the plurality of gate electrode layers.

6. The semiconductor memory device of claim 1, wherein the vertical channel layer comprises polysilicon doped with a first conductivity-type impurity.

7. The semiconductor memory device of claim 6, wherein the vertical channel layer comprises source/drain regions that are doped with a second conductivity-type impurity and are in contact with the plurality of source/drain contact layers.

8. The semiconductor memory device of claim 6, wherein the conductive layer comprises polysilicon doped with a first conductivity-type impurity.

9. The semiconductor memory device of claim 1, wherein the insulating isolation layer comprises aluminum oxide (Al₂O₃).

10. The semiconductor memory device of claim 1, wherein the vertical channel layer comprises a plurality of vertical channel layers.

11. The semiconductor memory device of claim 10, further comprising an isolation structure extending in a second direction, parallel to the upper surface of the substrate, to separate the stack structure into a plurality of device regions,
wherein at least one vertical channel layer of the plurality of vertical channel layers is provided in each of the plurality of device regions.

12. The semiconductor memory device of claim 1, wherein the vertical channel layer has a cylindrical structure, and
wherein the stack structure surrounds a side surface of the vertical channel layer

13. The semiconductor memory device of claim 1, further comprising a core insulating portion extending through the vertical channel layer in the first direction,
wherein the vertical channel layer surrounds a side surface of the core insulating portion.

14. A semiconductor memory device, comprising:
a conductive layer on a substrate and doped with a first conductivity-type impurity;
an insulating isolation layer on the conductive layer;
a plurality of source/drain contact layers on the insulating isolation layer, and spaced apart from each other in a first direction, perpendicular to an upper surface of the substrate;
a plurality of gate electrode layers respectively disposed between the plurality of source/drain contact layers;
a vertical channel layer extending through the plurality of source/drain contact layers, the plurality of gate electrode layers, and the insulating isolation layer to be connected to the conductive layer, and doped with a first conductivity-type impurity in a first concentration;
source/drain regions of the vertical channel layer that are doped with a second conductivity-type impurity and are in contact with the plurality of source/drain contact layers; and
a plurality of gate insulating layers between side surfaces of the plurality of gate electrode layers and the vertical channel layer, and between the plurality of gate electrode layers and the plurality of source/drain contact layers.

15. The semiconductor memory device of claim 14, wherein each of the plurality of gate insulating layers comprises a ferroelectric film and an interface insulating film between the ferroelectric film and the vertical channel layer.

16. The semiconductor memory device of claim 14, wherein the vertical channel layer comprises an end portion in the conductive layer.

17. The semiconductor memory device of claim 14, wherein the vertical channel layer and the conductive layer comprise polysilicon doped with a first conductivity-type impurity.

18. The semiconductor memory device of claim 14, further comprising a plurality of word lines respectively connected to the plurality of gate electrode layers, a ground line connected to source contact layers among the plurality of source/drain contact layers, and a bit line connected to drain contact layers among the plurality of source/drain contact layers.

19. The semiconductor memory device of claim 18, further comprising a channel bias line connected to the conductive layer.

20. A semiconductor memory device, comprising:
a conductive layer on a substrate;
an insulating isolation layer on the conductive layer;
a first stack structure on the insulating isolation layer, the first stack structure comprising a plurality of first source/drain contact layers arranged to be spaced apart from each other in a first direction, perpendicular to an upper surface of the substrate, and at least one first gate electrode layer respectively between the plurality of first source/drain contact layers;
a second stack structure on the first stack structure, the second stack structure comprising a plurality of second source/drain contact layers arranged to be spaced apart from each other in the first direction, and at least one second gate electrode layer respectively between the plurality of second source/drain contact layers;
a device isolation film between the first stack structure and the second stack structure;
a vertical channel layer extending through the first stack structure, the second stack structure, the device isolation film, and the insulating isolation layer, in contact with each of the plurality of first and second source/drain contact layers, and connected to the conductive layer; and
a gate insulating layer between each of the at least one first gate electrode layer and the vertical channel layer, and between each of the at least one second gate electrode layer and the vertical channel layer.
